(19) United States
(12) Patent Application Publication
(10) Pub. No.: US 2024/0110938 A1
(43) Pub. Date: Apr. 4, 2024

(54) CAPACITIVE MICROMECHANICAL ACCELEROMETER

(71) Applicant: AAC Kaitai Technologies (Wuhan) CO., LTD, Wuhan (CN)

(72) Inventors: Shitao Yan, Shenzhen (CN); Zhan Zhan, Shenzhen (CN); Shan Yang, Shenzhen (CN); Zhao Ma, Shenzhen (CN); Xiao Kan, Shenzhen (CN); Hongtao Peng, Shenzhen (CN); Yang Li, Shenzhen (CN); Kahkeen Lai, Singapore (SG); Veronica Tan, Singapore (SG)

(21) Appl. No.: 18/092,934

(22) Filed: Jan. 4, 2023

Related U.S. Application Data
(63) Continuation of application No. PCT/CN2022/124698, filed on Oct. 11, 2022.

(30) Foreign Application Priority Data
Sep. 23, 2022 (CN) 202211163971.9

(51) Int. Cl. G01P 15/125

(52) U.S. Cl. CPC G01P 15/125; G01P 2015/0831

(57) ABSTRACT

The present invention provides a capacitive micromechanical acceleromete. The capacitive micromechanical acceleromete includes a base with anchor points, at least one detection structure pair arranged on one side of the base and elastically connected to the anchor points, and a detection electrode spaced apart from each detection structure pair. Each detection structure pair includes two seesaw structures elastically connected to the base respectively. The seesaw structures are asymmetric about a rotation axis where the anchor points are located; asymmetric portions of the two seesaw structures are reversed and parallel. In a detection modality, changing directions of spacings formed between the two seesaw structures and the detection electrode are opposite. The capacitive micromechanical acceleromete can reduce the impact of the noise of the angular acceleration of the external rotation or the stress and other external factors on the detection of the accelerometer, and improving the detection accuracy.

### CROSS-REFERENCE TO RELATED APPLICATIONS

The application is a continuation of International Application No. PCT/CN2022/124698 filed on Oct. 11, 2022, which is incorporated herein by reference in its entireties.

### TECHNICAL FIELD

The present invention belongs to the technical field of acceleration detection, in particular, to a capacitive micromechanical accelerometer.

### BACKGROUND

In the related technology, some micromechanical accelerometers will use asymmetric seesaw structures for in-plane acceleration detection and out-plane acceleration detection.

However, an acceleration detection modality in an in-plane direction and a motion modality of an angular acceleration action in an out-plane direction will overlap, and an acceleration detection modality in the out-plane direction and a motion modality of an angular acceleration action in the in-plane direction will overlap. Therefore, the accelerometer with the seesaw structures for acceleration detection has poor ability to resist the impact of an angular acceleration in a corresponding external direction, which affects the detection accuracy of the accelerometer.

### SUMMARY

The present invention aims to provide a capacitive micromechanical accelerometer which can reduce the impact of noise of an angular acceleration of an external rotation on the detection of the accelerometer, thus improving the detection accuracy.

The technical solution of the present invention is as follows: a capacitive micromechanical accelerometer, including a base with anchor points, at least one detection structure pair arranged on one side of the base and elastically connected to the anchor points, and a detection electrode spaced apart from each detection structure pair, wherein each detection structure pair includes two seesaw structures elastically connected to the base respectively; the seesaw structures are asymmetric about a rotation axis where the anchor points are located; asymmetric portions of the two seesaw structures are reversed and parallel; in a detection modality, changing directions of spacings formed between the two seesaw structures and the detection electrode are opposite;
the two seesaw structures are used for being connected to reversed carrier drive signals respectively; and an acceleration detection result is obtained by means of analyzing changes of differential capacitors between the two seesaw structures and the detection electrode, and the carrier drive signals.

Further, in an initial state, the spacings between the various seesaw structures and the detection electrode are equal; and products obtained by multiplying areas of face-to-face regions of the various seesaw structures and the detection electrode by distances from centers of the face-to-face regions to the corresponding rotation axes are equal.

Further, in a direction perpendicular to an extending direction of the seesaw structures, the anchor points connected to the two seesaw structures directly face to each other; or,
in the direction perpendicular to the extending direction of the seesaw structures, the anchor points connected to the two seesaw structures are staggered; and the same ends of the two seesaw structures are flush with each other.

Further, the detection electrode includes an out-plane electrode; and the out-plane electrode is spaced apart from board surfaces of the seesaw structures and forms a corresponding out-plane detection capacitor.

Further, the detection electrode includes an out-plane electrode; and the out-plane electrode and the seesaw structures form out-plane detection capacitors respectively; or,
the detection electrode includes two out-plane electrodes; the out-plane electrodes and the various seesaw structures respectively form out-plane detection capacitors; and the two out-plane electrodes and two sides of the corresponding rotation axis of the same seesaw structure form corresponding out-plane detection capacitors.

Further, the capacitive micromechanical accelerometer includes two detection structure pairs; a lengthwise extending direction of the seesaw structures of one detection structure pair is in the first direction, and a lengthwise extending direction of the seesaw structures of the other detection structure pair is in the second direction; and the first direction and the second direction are perpendicular to each other.

Further, the two detection structure pairs are in rectangular arrangement; the two seesaw structures of one detection structure pair are respectively arranged on two opposite side edges of the rectangle; and the two seesaw structures of the other detection structure pair are respectively arranged on the other two opposite side edges of the rectangle.

Further, the detection electrode includes an in-plane electrode; and the in-plane electrode is spaced apart from side surfaces of the seesaw structures and forms a corresponding in-plane detection capacitor.

Further, the detection electrode includes an in-plane electrode; and the in-plane electrode and the seesaw structures form in-plane detection capacitors respectively; or,
the detection electrode includes two in-plane electrodes; the in-plane electrodes and the various seesaw structures respectively form in-plane detection capacitors; and the two in-plane electrodes are respectively located on two opposite sides of the same seesaw structure to form corresponding in-plane detection capacitors.

Further, the accelerometer further includes an upper cover that is arranged, in a spacing manner, on one side of each detection structure pair facing away from the base; and the detection electrode is arranged on the base and/or the upper cover.

The beneficial effects of the present invention lie in: the asymmetric portions of the two seesaw structures are reversed and parallel; the two seesaw structures can be connected to two carrier drive signals which are opposite in phase; and in the detection modality, the changing directions of the spacings formed between the two seesaw structures and the detection electrode are opposite. Therefore, accelerations in the corresponding directions can be further obtained by means of detecting changes of the differential capacitors formed between the two seesaw structures and the detection electrode, and the carrier drive signals. In addition, under the impact of the noise of the angular accelerations of the same rotation of the motion modality and the detection modality, when the base tilts due to stress and other external factors, the two seesaw structures will rotate and tilt in the same direction by taking the corresponding anchor points as rotation axes, causing common mode changes of the differential capacitors to cancel out the impact, thus reducing the impact of the noise of the angular acceleration of the external rotation or the stress and other external factors on the detection of the accelerometer, and improving the detection accuracy.

### BRIEF DESCRIPTION OF THE DRAWINGS

FIG. 1 shows a schematic structural diagram (above) of a capacitive micromechanical accelerometer for detecting an out-plane acceleration and a schematic structural diagram (below) of a detection modality according to the present invention;

FIG. 2 shows a schematic structural diagram of a detection modality of a capacitive micromechanical accelerometer for detecting an in-plane acceleration according to the present invention;

FIG. 3 is a schematic structural diagram of a capacitive micromechanical accelerometer of example 1 of the present invention;

FIG. 4 is a schematic structural diagram of a capacitive micromechanical accelerometer of example II of the present invention;

FIG. 5 is a schematic structural diagram of a capacitive micromechanical accelerometer of example III of the present invention;

FIG. 6 is a schematic structural diagram of a capacitive micromechanical accelerometer of example IV of the present invention;

FIG. 7 is a schematic structural diagram of a capacitive micromechanical accelerometer of example V of the present invention;

FIG. 8 is a schematic structural diagram of a capacitive micromechanical accelerometer of example VI of the present invention;

FIG. 9 is a schematic structural diagram of a capacitive micromechanical accelerometer of example VII of the present invention;

FIG. 10 is a schematic structural diagram of a capacitive micromechanical accelerometer of example VIII of the present invention;

FIG. 11 is a schematic structural diagram of a capacitive micromechanical accelerometer of example IX of the present invention;

FIG. 12 is a schematic structural diagram of a capacitive micromechanical accelerometer of example X of the present invention;

FIG. 13 is a schematic structural diagram of a capacitive micromechanical accelerometer of example XI of the present invention;

FIG. 14 is a schematic structural diagram of a capacitive micromechanical accelerometer of example XII of the present invention;

FIG. 15 is a schematic structural diagram of a capacitive micromechanical accelerometer of example XIII of the present invention; and

FIG. 16 is a schematic structural diagram of a capacitive micromechanical accelerometer of example XIV of the present invention.

### DETAILED DESCRIPTION OF THE EMBODIMENTS

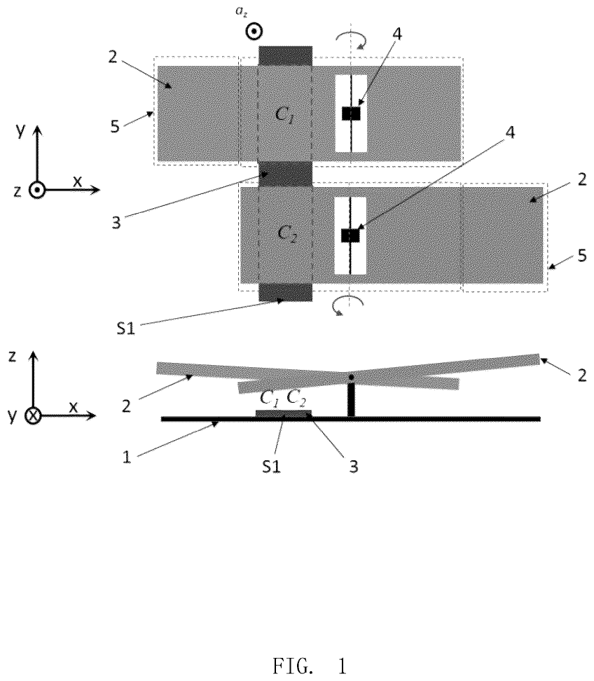

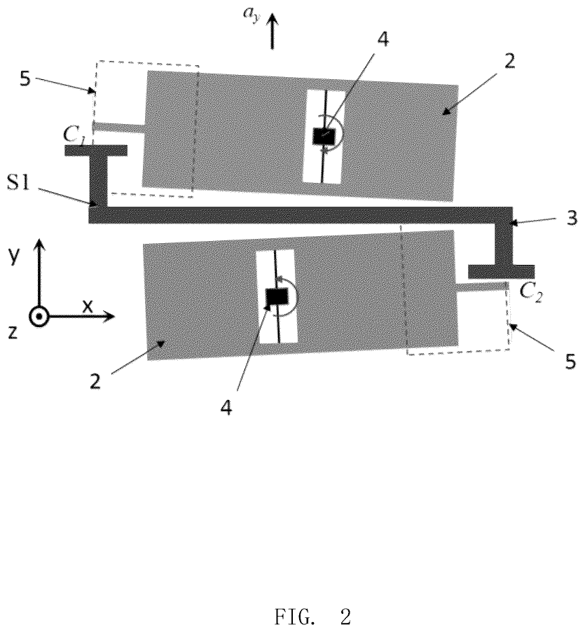

Referring to FIG. 1 to FIG. 2, a capacitive micromechanical accelerometer is provided, including a base 1 with anchor points 4, at least one detection structure pair arranged on one side of the base 1 and elastically connected to the anchor points 4, and a detection electrode 3 spaced apart from each detection structure pair. Each detection structure pair includes two seesaw structures 2 elastically connected to the base 1 respectively. The seesaw structures 2 are asymmetric about a rotation axis where the anchor points 4 are located. Asymmetric portions 5 of the two seesaw structures 2 are reversed and parallel. In a detection modality, changing directions of spacings formed between the two seesaw structures 2 and the detection electrode 3 are opposite.

The two seesaw structures 2 are used for being connected to reversed carrier drive signals respectively. An acceleration detection result is obtained by means of analyzing changes of differential capacitors between the two seesaw structures 2 and the detection electrode 3, and the carrier drive signals.

The asymmetric portions 5 of the two seesaw structures 2 are reversed and parallel; the two seesaw structures 2 can be connected to two carrier drive signals which are opposite in phase; and in the detection modality, the changing directions of the spacings formed between the two seesaw structures 2 and the detection electrode 3 are opposite. Therefore, accelerations in the corresponding directions can be further obtained by means of detecting changes of the differential capacitors formed between the two seesaw structures 2 and the detection electrode 3, and the carrier drive signals. In addition, under the impact of the noise of the angular accelerations of the same rotation of the motion modality and the detection modality, when the base 1 tilts due to stress and other external factors, the two seesaw structures 2 will rotate and tilt in the same direction by taking the corresponding anchor points 4 as rotation axes, causing common mode changes of the differential capacitors to cancel out the impact, thus reducing the impact of the noise of the angular acceleration of the external rotation or the stress and other external factors on the detection of the accelerometer, and improving the detection accuracy.

In-plane moments of inertia of the two seesaw structures 2 are matched, and out-plane moments of inertia are matched, that is, the shapes of the seesaw structures 2 can be the same or different. An out-plane rotation axis of the single seesaw structure 2 is located at a straight line where the anchor points 4 and a spring are located, and an in-plane motion rotation axis is intersected with the out-plane rotation axis and is perpendicular to the seesaw structure 2.

In the initial state, spacings between the various seesaw structures 2 and the detection electrode 3 are equal, and products obtained by multiplying areas of face-to-face regions of the various seesaw structures 2 and the detection electrode 3 by distances from centers of the face-to-face regions to the corresponding rotation axes are equal. As such, an acceleration corresponding to the direction of the detection modality can be in direct proportion to a distance between each seesaw structure 2 and the detection electrode 3, so that a corresponding acceleration can be further obtained by means of detecting the changes of the differential capacitors.

In a direction perpendicular to an extending direction of the seesaw structures 2, the anchor points 4 connected to the two seesaw structures 2 directly face to each other; or, in the direction perpendicular to the extending direction of the seesaw structures 2, the anchor points 4 connected to the two seesaw structures 2 are staggered. The same ends of the two seesaw structures 2 are flush with each other, which makes the layout save more spaces. It should be understood that portions of the seesaw structures 2 that correspond to the anchor points 4 can be set according to an actual situation. In some implementations, the anchor points 4 connected to the two seesaw structures 2 can be staggered, and the same ends of the two seesaw structures 2 can also be staggered. Each detection structure pair is a central symmetry structure. In addition, the detection electrode 3 may be in a shape of a rectangular flat plate, or may also be bent according to an actual situation, as long as it can ensure the following facts: In the initial state, the spacings between the various seesaw structures 2 and the detection electrode 3 are equal, and products obtained by multiplying areas of face-to-face regions of the various seesaw structures and the detection electrode by distances from centers of the face-to-face regions to the corresponding rotation axes are equal.

The detection electrode 3 can include an out-plane electrode. The out-plane electrode is spaced apart from board surfaces of the seesaw structures 2 and forms a corresponding out-plane detection capacitor. An out-plane acceleration can be further obtained by means of detecting changes of the out-plane detection capacitor.

The detection electrode 3 can include an in-plane electrode. The in-plane electrode is spaced apart from side surfaces of the seesaw structures 2 and forms a corresponding in-plane detection capacitor. An in-plane acceleration can be further obtained by means of detecting changes of the in-plane detection capacitor.

For the same detection structure pair, the detection structure pair can form the out-plane detection capacitor and the in-plane detection capacitor simultaneously with the out-plane electrode and the in-plane electrode. Therefore, the same detection structure can detect both the out-plane acceleration and the in-plane acceleration.

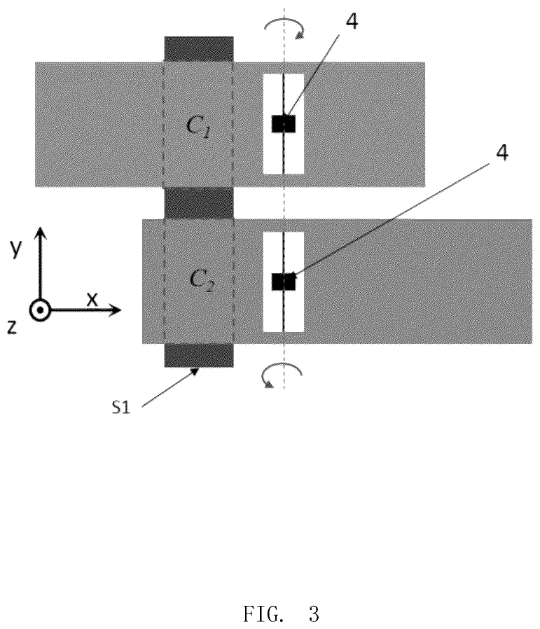

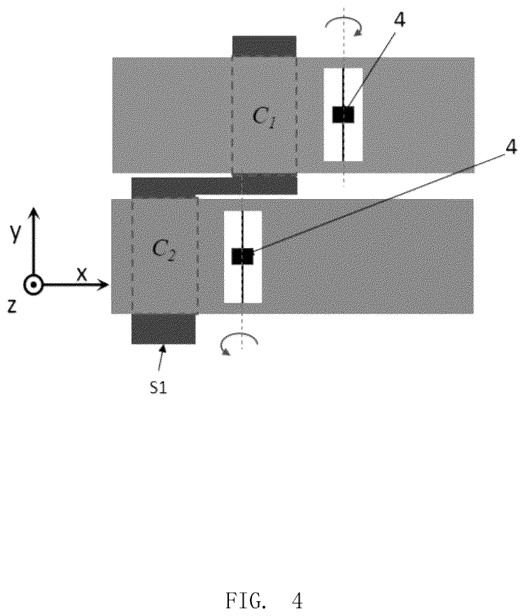

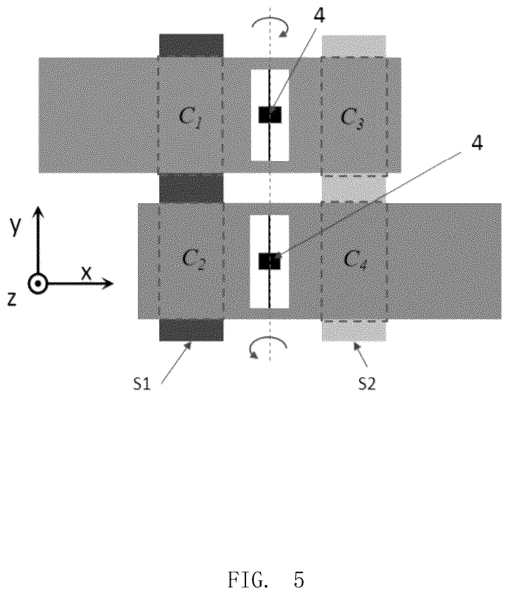

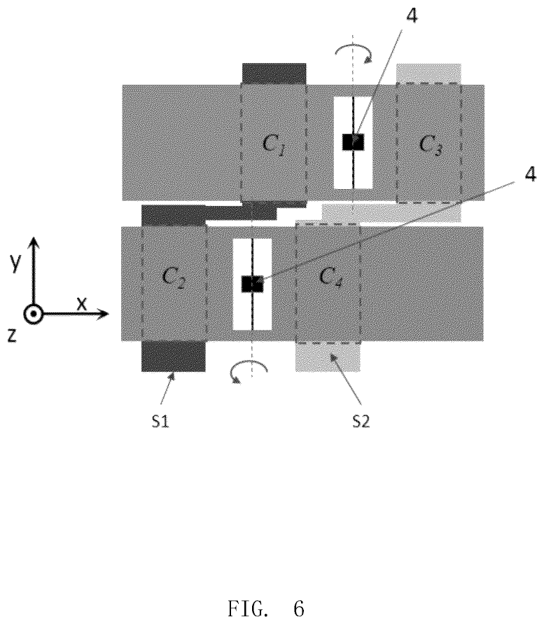

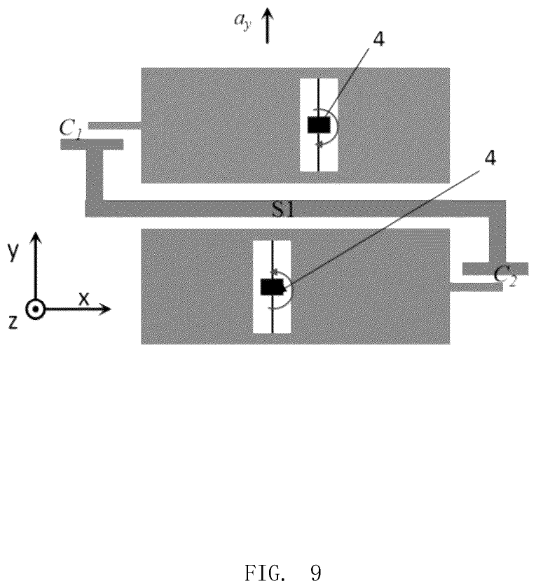

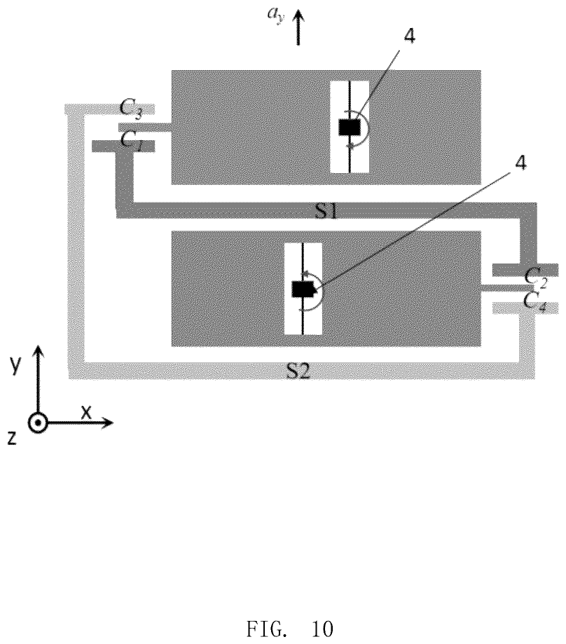

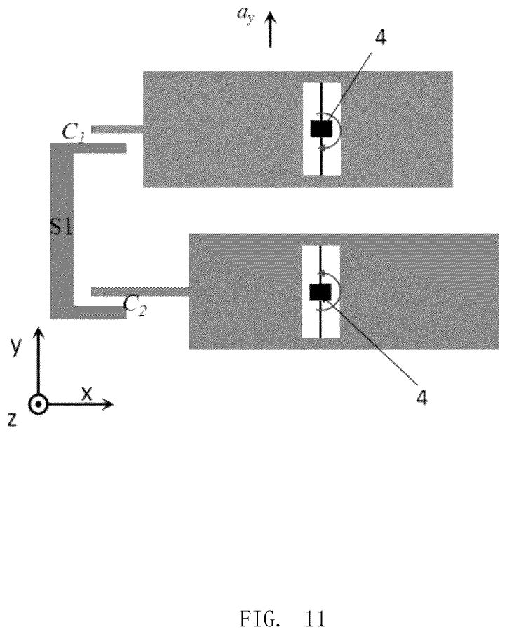

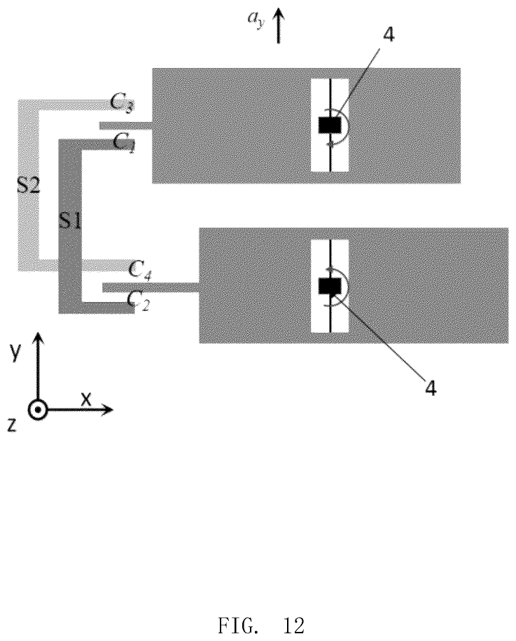

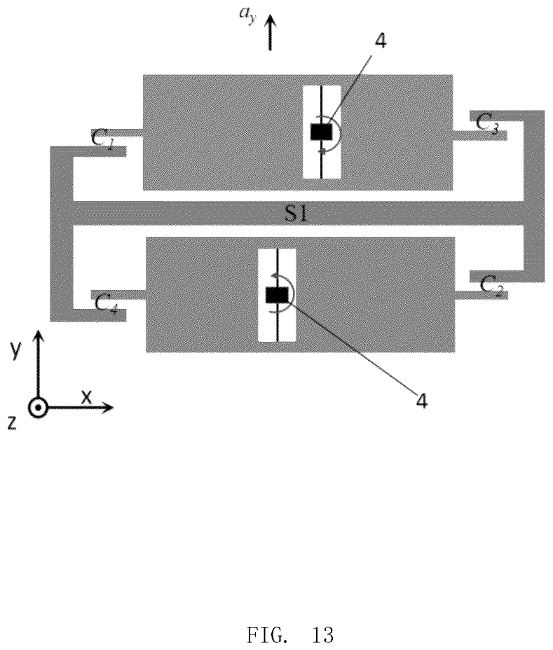

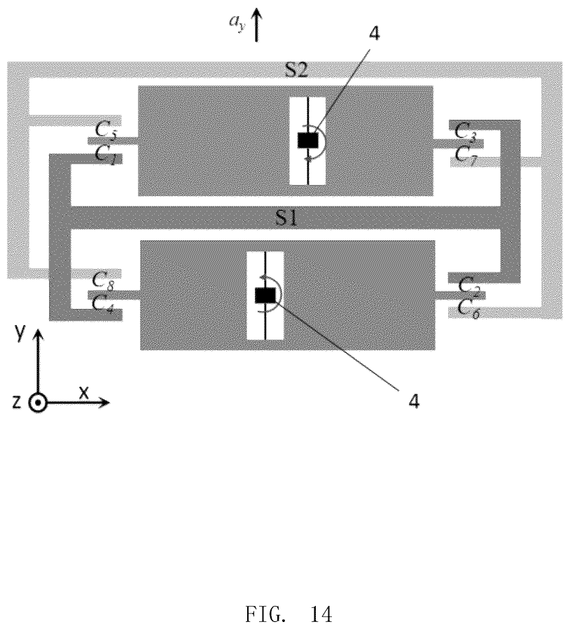

Referring to FIG. 3, FIG. 4, FIG. 5, FIG. 6, FIG. 9, FIG. 10, FIG. 11, FIG. 12, FIG. 13 and FIG. 14, the accelerometer can include one detection structure pair. At this time, the two seesaw structures 2 of the detection structure pair are spaced apart from each other and parallel to each other.

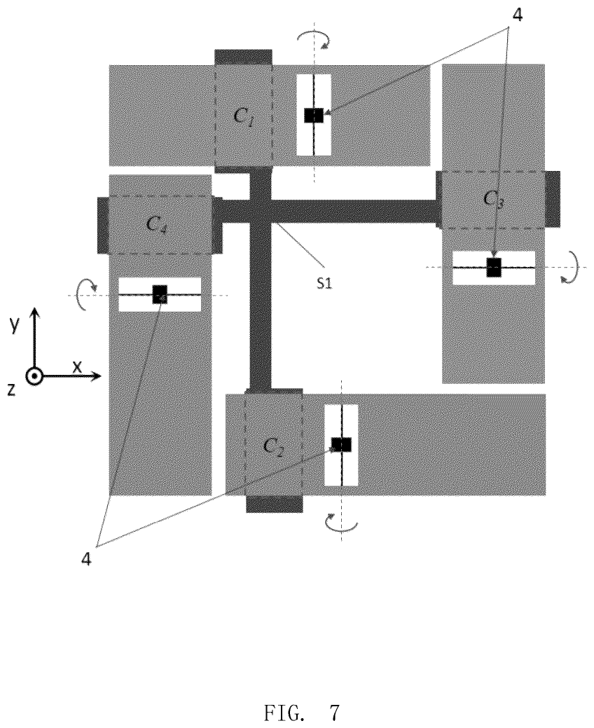

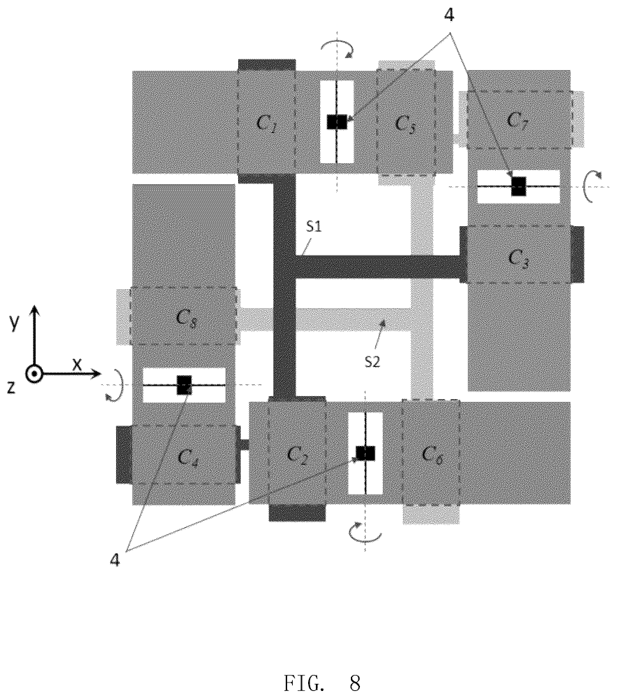

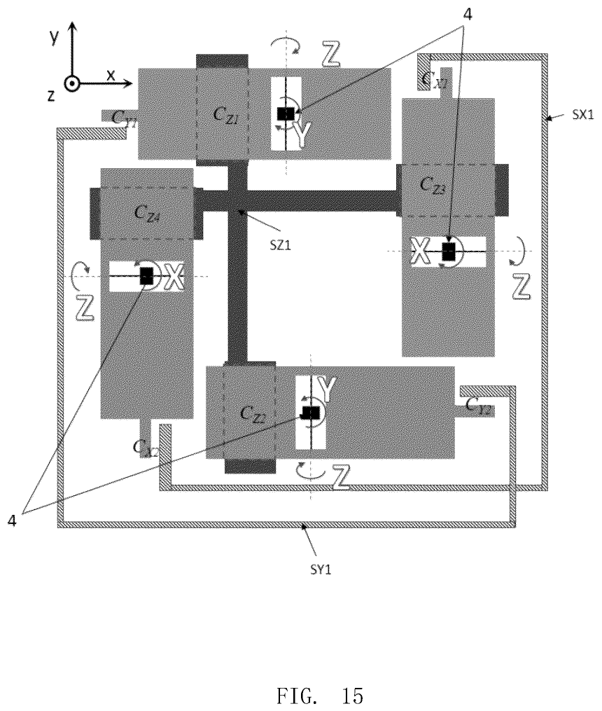

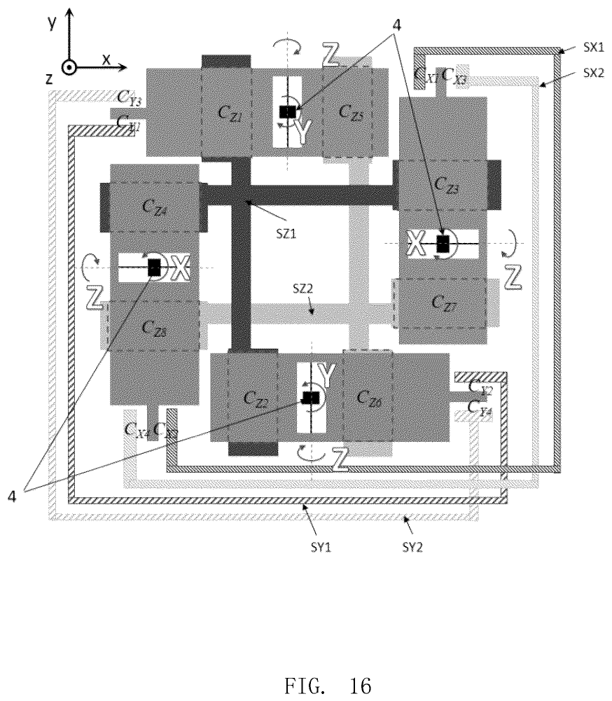

Referring to FIG. 7, FIG. 8, FIG. 15 and FIG. 16, the accelerometer can include two detection structure pairs. The seesaw structures 2 of different detection structure pairs have different extending directions. When there are two detection structure pairs, the extending directions of the seesaw structures 2 of different detection structure pairs are perpendicular to each other. Therefore, straight lines where central lines of the seesaw structures 2 of the two detection structure pairs are intersected t form a rectangle The capacitive micromechanical accelerometer includes two detection structure pairs. The lengthwise extending directions of the seesaw structures 2 of one detection structure pair is in the first direction, and the lengthwise extending directions of the seesaw structures 2 of one detection structure pair is in the second direction. The first direction and the second direction are perpendicular to each other. Preferably, the two detection structure pairs are in rectangular arrangement. The two seesaw structures 2 of one detection structure pair are respectively arranged on two opposite side edges of the rectangle, and the two seesaw structures 2 of one detection structure pair are respectively arranged on the other two opposite side edges of the rectangle. The same detection structure pair can detect both the out-plane acceleration and the in-plane acceleration, and the lengthwise extending directions of the seesaw structures 2 of the two detection structure pairs are different, so that triaxial angular accelerations can be detected, and the space can be saved. It should be understood that the accelerometer can also include more detection structure pairs, for example, three, four, or five detection structure pairs. By means of arranging two or more detection structure pairs, the detection sensitivity can be improved.

The detection electrode 3 can include an out-plane electrode. The out-plane electrode and the various seesaw structures 2 respectively form out-plane detection capacitors. Or, the detection electrode 3 can include two out-plane electrodes. The out-plane electrodes and the various seesaw structures 2 respectively form out-plane detection capacitors. Furthermore, the two out-plane electrodes respectively form corresponding out-plane detection capacitors with two sides of the corresponding rotation axis of the same seesaw structure 2. By the adoption of a scheme of differential detection of an acceleration by two out-plane electrodes, the anti-interference capacity can be further improved, and the detection sensitivity of the out-plane acceleration is improved.

The detection electrode 3 includes an in-plane electrode. The in-plane electrode and the various seesaw structures 2 respectively form in-plane detection capacitors. Or, the detection electrode 3 includes two in-plane electrodes. The in-plane electrodes and the various seesaw structures 2 respectively form in-plane detection capacitors. Furthermore, the two in-plane electrodes respectively form corresponding in-plane detection capacitors with two opposite sides of the same seesaw structure 2. By the adoption of a scheme of differential detection of an acceleration by two in-plane electrodes, the anti-interference capacity can be further improved, and the detection sensitivity of the out-plane acceleration is improved.

The accelerometer further includes an upper cover that is arranged, in a spacing manner, on one side of each detection structure pair facing away from the base 1. The detection electrode 3 is arranged on the base 1 and/or the upper cover. When the detection electrode 3 includes the out-plane electrode, the out-plane electrode can be attached to the base 1 and/or the upper cover.

The out-plane electrode is parallel to the corresponding seesaw structures 2. When the detection electrode 3 includes the in-plane electrode, the in-plane electrode can be perpendicularly connected to the base 1 and/or the upper cover, and is spaced apart from the side surfaces of the corresponding seesaw structures 2 to form the in-plane detection capacitors.

Based on the capacitive micromechanical accelerometers of all the foregoing schemes, an accelerometer detection method is provided, including the following steps:
respectively connecting reversed carrier drive signals to the paired seesaw structures 2;
detecting changes of differential capacitors between the two seesaw structures 2 and the detection electrode 3; and
obtaining an acceleration detection result according to the carrier drive signals and the changes of the differential capacitors.

For out-plane acceleration detection, Z-axis out-plane acceleration detection is taken as an example:

A normal phase carrier drive signal Vₚ and a reversed phase carrier drive signal −Vₚ are respectively connected to the two seesaw structures 2 from the corresponding anchor points 4. An acceleration a_{z} in an out-plane Z-axis direction makes the two seesaw structures 2 to rotate around the Y-axis in opposite directions. Assuming that overlapping areas of plates of differential detection capacitors C₁ and C₂ are equal at this time, distances from the plates to the rotation axes are equal, and spacings of the differential detection capacitors C₁ and C₂ relatively change by z₁ and −z₂ (angles of seesaws change in a small range when the accelerometer works, so that corresponding capacitive moving plates on the seesaw structures 2 can approximately do translation motion). By means of designing the seesaw structures 2, z₁≈z₂=z under the action of an acceleration, and there are:

C₁=ε*A/(d+z);C₂=ε*A/(d−z), where ε is a dielectric constant of an inter-plate medium; A is a plate area; and d is an initial spacing.

Since the moving plates of the differential detection capacitors C₁ and C₂ are respectively connected to the normal phase carrier Vₚ and the reversed phase carrier −Vₚ through the anchor points 4 of the seesaw structures 2, so that the out-plane electrode S1 (i.e. a capacitive fixed plate) is connected to a high-resistance or low-resistance preamplifier and a subsequent detection circuit to obtain:

aₜₑₛₜ∝Vₚ*(C₁−C₂)=Vₚ*ε*A(1/(d+z)−1/(d−z)). Since z<<d,1/(d+z)−1/(d−z)≈−2z/d².

Under the condition of z∝a_{z}, a Z-axis acceleration can be detected by means of detecting changes of the differential capacitors.

When the accelerometer is interfered by the noise of an angular acceleration of rotation around the Y axis, the two seesaw structures 2 rotate towards the same direction, and the spacings of the differential detection capacitors C₁ and C₂ have the same changes of z₁′≈z₂′. After the differential carriers and a capacitance detection circuit are connected, the changes are canceled out, so that an output result will not be affected, and the detection accuracy can be improved.

When the base 1 (or the upper cover or other structures) where the detection electrode 3 is located tilts around the Y axis due to stress or other external factors, the spacings of the differential detection capacitors C₁ and C₂ have the same changes of z₁″≈z₂″, so that the changes can also be canceled out. The output result will not be affected, and the detection accuracy can be improved.

For in-plane acceleration detection, Y-axis in-plane acceleration detection is taken as an example:

A normal phase carrier drive signal Vₚ and a reversed phase carrier drive signal −Vₚ are respectively connected to the two seesaw structures 2 from the corresponding anchor points 4.

An acceleration ay in an in-plane Y-axis direction makes the two seesaw structures 2 to rotate around the Z-axis in opposite directions. Spacings of the differential detection capacitors C₁ and C₂ relatively change by y₁ and −y₂ (angles of the seesaw structures 2 change in a small range when the accelerometer works, so that corresponding capacitive moving plates on the seesaw structures 2 can approximately do translation motion). By means of designing the seesaw structures 2, y₁≈y₂=y under the action of an acceleration, and there are:
C₁=ε*A/(d+y); C₂=ε*A/(d−y), where c is a dielectric constant of an inter-plate medium; A is a plate area; and d is an initial spacing.

Since the moving plates of the differential detection capacitors C₁ and C₂ are respectively connected to the normal phase carrier Vₚ and the reversed phase carrier −Vₚ through the anchor points 4 of the seesaw structures 2, so that a capacitance detection electrode S1 (i.e. a capacitive fixed plate) is connected to a high-resistance or low-resistance preamplifier and a subsequent detection circuit to obtain:

aₜₑₛₜ∝Vₚ*(C₁−C₂)=Vₚ*ε*A(1/(d+y)−1/(d−y)),E F y<d,1/(d+y)−1/(d−y)≈−2y/d².

Under the condition of y∝ay, a Y-axis acceleration can be detected by means of detecting changes of the differential capacitors.

When the accelerometer is interfered by the noise of an angular acceleration of rotation around the Z axis, the two seesaw structures 2 rotate towards the same direction, and the spacings of the differential detection capacitors C1 and C2 have the same changes of y1′≈y2′. After the differential carriers and a capacitance detection circuit are connected, the changes are canceled out, so that an output result will not be affected, and the detection accuracy can be improved.

On the basis of the structure of the foregoing accelerometer and the detection method, some specific accelerometer setting examples and corresponding accelerometer detection methods are provided below:

### Example I

Referring to FIG. 3, the accelerometer includes one detection structure pair and an out-plane electrode S1 spaced apart from the detection structure pair. Anchor points 4 corresponding to two seesaw structures in the detection structure pair are flush with each other in a direction perpendicular to an extending direction of the seesaw structures. Therefore, the same ends of the two seesaw structures are not flush. However, rotation axes in a detection modality are collinear. The out-plane electrode S1 is rectangular, which is arranged on the same sides of the two anchor points 4. An extending direction of the out-plane electrode S1 is perpendicular to the extending direction of the seesaw structures.

C₁=ε*A/(d+z);C₂=ε*A/(d−z).

Therefore, the corresponding acceleration aₜₑₛₜ∝Vₚ*(C₁−C₂) can be detected and obtained by detecting changes of the differential capacitors.

### Example II

Referring to FIG. 4, the accelerometer includes one detection structure pair and an in-plane electrode S1 spaced apart from the detection structure pair. Anchor points 4 corresponding to two seesaw structures in the detection structure pair are staggered from each other in a direction perpendicular to an extending direction of the seesaw structures. Furthermore, the same ends of the two seesaw structures are flush with each other. Due to this layout, the space can be saved. The in-plane electrode S1 is arranged on the same sides of the two anchor points 4 and is bent.

C₁=ε*A/(d+z);C₂=ε*A/(d−z).

Therefore, the corresponding acceleration aₜₑₛₜ∝Vₚ*(C₁−C₂) can be detected and obtained by detecting changes of the differential capacitors.

### Example III

Referring to FIG. 5, based on Example I, the accelerometer further includes an out-plane electrode S2 spaced apart from the detection structure pair. The out-plane electrode S1 and the out-plane electrode S2 are respectively located on two opposite sides of the corresponding anchor points 4.

C₁=ε*A/(d+z);C₂=ε*A/(d−z);C₃=ε*A/(d−z);C₄=ε*A/(d+z).

Therefore, aₜₑₛₜ∝Vₚ*(C₁−C₂)−Vₚ*(C₃−C₄). The out-plane electrode S1 and the out-plane electrode S2 are separately subjected to single-path detection and are then differentiated, so that corresponding accelerations can be detected and obtained. Furthermore, this differential detection can further improve the anti-interference capacity and improve the detection sensitivity.

### Example IV

Referring to FIG. 6, based on Example II, the accelerometer further includes an out-plane electrode S2 spaced apart from the detection structure pair. The out-plane electrode S1 and the out-plane electrode S2 are respectively located on two opposite sides of the corresponding anchor points 4. The out-plane electrode S1 and the out-plane electrode S2 have the same shapes. The layout of this scheme saves more space.

C₁=c*A/(d+z);C₂=ε*A/(d−z);C₃=ε*A/(d−z);C₄=ε*A/(d+z).

Therefore, aₜₑₛₜ∝Vₚ*(C₁−C₂)−Vₚ*(C₃−C₄). The out-plane electrode S1 and the out-plane electrode S2 are separately subjected to single-path detection and are then differentiated, so that corresponding accelerations can be detected and obtained. Furthermore, this differential detection can further improve the anti-interference capacity and improve the detection sensitivity.

### Example V

Referring to FIG. 7, the accelerometer includes two detection structure pairs and an out-plane electrode S1 spaced apart from the detection structure pairs. Four seesaw structures are close to each other end to end to form a rectangular ring. The out-plane electrode S1 has four end portions, and the four end portions and the four seesaw structures form corresponding out-plane detection capacitors. The seesaw structures on two opposite side edges of the rectangle form one detection structure pair, and the out-plane detection capacitor formed by the same detection structure pair is located on the same sides of the corresponding anchor points 4.

C₁=ε*A/(d+z);C₂=C*A/(d+z);C₃=ε*A/(d+z);C₄=ε*A/(d−z).

Therefore, aₜₑₛₜ∝Vₚ*(C₁−C₂+C₃−C₄). The out-plane electrode S1 is subjected to single-path detection, and every two rotation axes are parallel, but not collinear. Compared with an accelerometer with two seesaw structures, the accelerometer with one more group of orthogonal seesaw structures has the advantages that the acceleration detection sensitivity is doubled, and the accuracy is higher.

### Example VI

Referring to FIG. 8, based on Example V, the accelerometer further includes an out-plane electrode S2. Furthermore, the out-plane electrode S2 and the out-plane electrode S1 are in central symmetry.

C₁=ε*A/(d+z);C₂=ε*A/(d−z);C₃=ε*A/(d+z);C₄=ε*A/(d−z)

C₅=ε*A/(d−z);C₆=ε*A/(d+z);C₇=ε*A/(d−z);C₈=ε*A/(d+z).

Therefore, aₜₑₛₜ∝Vₚ*(C₁−C₂+C₃−C₄)−Vₚ*(C₅−C₆+C₇−C₈). The out-plane electrode S1 and the out-plane electrode S2 are separately subjected to single-path detection and are then differentiated, and every two rotation axes are parallel. This differential detection further improves the anti-interference capacity and improves the detection sensitivity. With one more group of orthogonal seesaw structures, the acceleration detection sensitivity can be doubled, and the accuracy can be higher.

### Example VII

Referring to FIG. 9, the accelerometer includes one detection structure pair and an in-plane electrode S1 spaced apart from the detection structure pair. Anchor points 4 corresponding to two seesaw structures in the detection structure pair are staggered from each other in a direction perpendicular to an extending direction of the seesaw structures. Therefore, the same ends of the two seesaw structures are flush with each other, and the layout saves more space. One end of each of asymmetric portions 5 of the two seesaw structures extends outwards to form a moving plate. The in-plane electrode S1 has two plates which respectively form in-plane detection capacitors together with the moving plates. It should be understood that the plates in the in-plane electrode S1 are electrically connected. The electrically connected structure can be located between the two seesaw structures or wound outside the seesaw structures. The structural form of the in-plane electrode S1 is not limited here.

C₁=ε*A/(d+y);C₂=ε*A/(d−y).

Therefore, aₜₑₛₜ∝Vₚ*(C₁−C₂), the corresponding in-plane acceleration can be detected and obtained by detecting changes of the differential capacitors.

### Example VIII

Referring to FIG. 10, based on Example VII, the accelerometer further includes an in-plane electrode S2 spaced apart from the detection structure pair. The in-plane electrode S2 also has two plates corresponding to the moving plate. The corresponding plates of the in-plane electrode S1 and the in-plane electrode S2 are oppositely arranged on two sides of the corresponding moving plate.

C₁=ε*A/(d+y);C₂=ε*A/(d−y);C₃=ε*A/(d−y);C₄=ε*A/(d+y).

Therefore, aₜₑₛₜ∝Vₚ*(C₁−C₂)−Vₚ*(C₃−C₄). The in-plane electrode S1 and the in-plane electrode S2 are separately subjected to single-path detection and are then differentiated, so that corresponding in-plane accelerations can be detected and obtained, and rotation axes are parallel (in the Z-axis direction). The detection method including single-path detection and differentiation further improves the anti-interference capacity and improves the detection sensitivity (doubled).

### Example IX

Referring to FIG. 11, the accelerometer includes one detection structure pair and an in-plane electrode S1 spaced apart from the detection structure pair. Anchor points 4 corresponding to two seesaw structures in the detection structure pair are flush with each other in a direction perpendicular to an extending direction of the seesaw structures. Therefore, the same ends of the two seesaw structures are staggered from each other, and the same ends of the seesaw structures extend outwards to form moving plates. The in-plane electrode S1 has two plates which respectively form in-plane detection capacitors together with the moving plates. Distances from the two in-plane detection electrodes to the corresponding anchor points 4 are equal. By means of arranging the in-plane detection electrode S1 at the same end of the detection structure pair, the electrodes are routed more closely, and the coupling degree is lower.

C₁=ε*A/(d+y);C₂=ε*A/(d−y).

Therefore, aₜₑₛₜ∝Vₚ*(C₁−C₂), the corresponding in-plane acceleration can be detected and obtained by detecting changes of the differential capacitors.

### Example X

Referring to FIG. 12, based on Example IX, the accelerometer further includes an in-plane electrode S2 spaced apart from the detection structure pair. The in-plane electrode S2 and sides of the moving plates facing away from the in-plane electrode S1 form in-plane detection capacitors respectively.

C₁=ε*A/(d+y);C₂=ε*A/(d−y);C₃=ε*A/(d−y);C₄=ε*A/(d+y).

Therefore, aₜₑₛₜ∝Vₚ*(C₁−C₂)−Vₚ*(C₃−C₄). The in-plane electrode S1 and the in-plane electrode S2 are separately subjected to single-path detection and are then differentiated, so that corresponding in-plane accelerations can be detected and obtained, and rotation axes are parallel (in the Z-axis direction). The detection method including single-path detection and differentiation further improves the anti-interference capacity and improves the detection sensitivity (doubled). Furthermore, the electrodes are routed more closely, and the coupling degree is lower.

### Example XI

Referring to FIG. 13, based on Example VII, two ends of the seesaw structures are provided with moving plates. The in-plane electrode S1 and the various moving plates form in-plane detection capacitors, thus forming more detection positions to further improve the acceleration detection sensitivity.

C₁=*A/(d+y₁);C₂=ε*A/(d−y₁);C₃=ε*A/(d+y₂);C₄=ε*A/(d−y₂).

Therefore, aₜₑₛₜ∝Vₚ*(C₁−C₂+C₃−C₄), the corresponding in-plane acceleration can be detected and obtained by detecting changes of the differential capacitors.

### Example XII

Referring to FIG. 14, based on Example XI, the accelerometer further includes an in-plane electrode S2. The in-plane electrode S2 and sides of the various moving plates facing away from the in-plane electrode S2 form corresponding in-plane detection capacitors respectively.

C₁=ε*A/(d+y₁);C₂=ε*A/(d−y₁);C₃=ε*A/(d+y₂);C₄=ε*A/(d−y₂);C₈=ε*A/(d−y₁);C₆=ε*A/(d+y₁);C₇=ε*A/(d−y₂);C=ε*A/(d+y₂).

Therefore, aₜₑₛₜ∝Vₚ*(C₁−C₂+C₃−C₄)−Vₚ*(C₅−C₆+C₇−C₈). Corresponding in-plane accelerations can be detected and obtained by detecting changes of the differential capacitors.

Furthermore, the in-plane electrode S1 and the in-plane electrode S2 are separately subjected to single-path detection and are then differentiated, and rotation axes are parallel (in the Z-axis direction). This differential detection further improves the anti-interference capacity and improves the detection sensitivity (doubled). Furthermore, more detection positions further improve the acceleration detection sensitivity.

### Example XIII

Referring to FIG. 15, the accelerometer includes two detection structure pairs and an out-plane electrode SZ1, an in-plane electrode SY1 and an in-plane electrode SX1 which are spaced apart from the detection structure pairs. Four seesaw structures are close to each other end to end to form a ring where every two seesaw structures are parallel to each other. The out-plane electrode SZ1 has four end portions, and the four end portions and the four seesaw structures form corresponding Z-axis out-plane detection capacitors. The seesaw structures on two opposite side edges of the rectangle form one detection structure pair, and the out-plane detection capacitor formed by the same detection structure pair is located on the same sides of the corresponding anchor points 4. One end of each of asymmetric portions 5 of the seesaw structures of the same detection structure pair is provided with a moving plate. The in-plane electrode SY1 and the moving plates of one detection structure pair form Y-axis in-plane differential detection capacitors. The in-plane electrode SX1 and the moving plates of one detection structure pair form X-axis in-plane differential detection capacitors.

Therefore, for Z-axis acceleration detection:

C_{Z1}=ε*A_{Z}/(d_{Z}+z);C_{Z2}=ε*A_{Z}/(d_{Z}−z);C_{Z3}=ε*A_{Z}/(d_{Z}+z);C_{Z4}=ε*A_{Z}/(d_{Z}−z).

a_{Ztest}∝Vₚ*(C_{Z1}−C_{Z2}+C_{Z3}−C_{Z4}), a Z-axis acceleration can be measured by means of detecting variations of the Z-axis out-plane differential detection capacitors.

For Y-axis acceleration detection:

C_{Y1}=ε*A_{Y}/(d_{Y}+y);C_{Y2}=ε*A_{Y}/(d_{Y}−y).

a_{Ytest}∝Vₚ*(C_{Y1}−C_{Y2}), a Y-axis acceleration can be measured by means of detecting variations of the Y-axis out-plane differential detection capacitors.

For X-axis acceleration detection:

C_{X1}=ε*A_{X}/(d_{X}+x);C_{X2}=ε*A_{X}/(d_{X}−x);

a_{Xtest}∝Vₚ*(C_{X1}−C_{X2}), a X-axis acceleration can be measured by means of detecting variations of the X-axis out-plane differential detection capacitors.

In addition, by means of the implementation of this scheme, when the accelerometer is interfered by the noise of an angular acceleration of external rotation, for the acceleration detection in any direction, the differential detection capacitors can generate common mode changes to cancel off the impact, thus reducing the impact of the noise. In addition, when the base (or the upper cover or other structures) where the out-plane detection electrode is located tilts due to external stress or other factors, the Z-axis out-plane differential detection capacitors will generate common mode changes to cancel out the impact, thus reducing the impact of the external stress on the Z-axis acceleration.

### Example XIV

Referring to FIG. 16, based on Example XIII, the accelerometer further includes an out-plane electrode SZ2, an in-plane electrode SY2 and an in-plane electrode SX2. The out-plane electrode SZ2 and the out-plane electrode SZ1 are in central symmetry. The in-plane electrode SY2 and the in-plane electrode SY1 respectively form the Y-axis in-plane detection capacitors on two sides of the corresponding moving plates. The in-plane electrode SX2 and the in-plane electrode SX1 respectively form X-axis in-plane detection capacitors on two sides of the corresponding moving plate.

Therefore, for Z-axis acceleration detection:

C_{Z1}=ε*A_{Z}z/(d_{Z}+z);C_{Z2}=C*A_{Z}/(d_{Z}−z);C_{Z3}=*A_{Z}/(d_{Z}+z);C_{Z4}=C*A_{Z}/(d_{Z}−z);

C_{Z5}=ε*A_{Z}/(d_{Z}−z);C_{Z6}=ε*A_{Z}/(d_{Z}+z);C_{Z7}=C*A_{Z}/(d_{Z}−z);C_{Z8}=ε*A_{Z}/(d_{Z}+z);

a_{Ztest}∝Vₚ*(C_{Z1}−C_{Z2}+C_{Z3}−C_{Z4})−Vₚ*(C_{Z5}−C_{Z6}+C_{Z7}−C_{Z8}), the out-plane electrode SZ1 and the out-plane electrode SZ2 are separately subjected to single-path detection and are then differentiated to detect and obtain a Z-axis out-plane acceleration.

For Y-axis acceleration detection:

C_{Y1}=*A_{Y}/(d_{Y}+y);C_{Y2}=ε*A_{Y}/(d_{Y}−y);

C_{Y3}=*A_{Y}/(d_{Y}−y);C_{Y4}=ε*A_{Y}/(d_{Y}+y);

a_{Ytest}∝Vₚ*(C_{Y1}−C_{Y2})−Vₚ*(C_{Y3}−C_{Y4}), the in-plane electrode SY1 and the in-plane electrode SY2 are separately subjected to single-path detection and are then differentiated to detect and obtain a Y-axis in-plane acceleration.

For X-axis acceleration detection:

C_{X1}=ε*A_{X}/(d_{X}+x);C_{X2}=C*A_{X}/(d_{X}−x);

C_{X3}=ε*A_{X}/(d_{X}+x);C_{X4}=C*A_{X}/(d_{X}−x);

a_{Xtest}∝Vₚ*(C_{X1}−C_{X2})−Vₚ*(C_{X3}−C_{X4}), the in-plane electrode SX1 and the in-plane electrode SX2 are separately subjected to single-path detection and are then differentiated to detect and obtain a X-axis in-plane acceleration.

Based on Example XIII, in this scheme, the differential detection of each axis further improves the anti-interference capacity and improves the detection sensitivity (doubled).

It should be understood that in all the foregoing test examples, an acceleration is in direct proportion to a variation of a corresponding differential capacitor. Therefore, a detected variation of the corresponding differential capacitor is multiplied by a corresponding coefficient. The coefficient can be obtained according to a corresponding implementation by means of calibration, testing and the like.

The foregoing is merely illustrative of embodiments of the present invention, and it should be noted that modifications may be made to those skilled in the art without departing from the spirit of the invention, but are intended to be within the scope of the invention.

What is claimed is:

1. A capacitive micromechanical accelerometer, comprising a base with anchor points, at least one detection structure pair arranged on one side of the base and elastically connected to the anchor points, and a detection electrode spaced apart from each detection structure pair, wherein each detection structure pair comprises two seesaw structures elastically connected to the base respectively; the seesaw structures are asymmetric about a rotation axis where the anchor points are located; asymmetric portions of the two seesaw structures are reversed and parallel; in a detection modality, changing directions of spacings formed between the two seesaw structures and the detection electrode are opposite;
the two seesaw structures are used for being connected to reversed carrier drive signals respectively; and an acceleration detection result is obtained by means of analyzing changes of differential capacitors between the two seesaw structures and the detection electrode, and the carrier drive signals.

2. The capacitive micromechanical accelerometer according to claim 1, wherein in an initial state, the spacings between the various seesaw structures and the detection electrode are equal;
and products obtained by multiplying areas of face-to-face regions of the various seesaw structures and the detection electrode by distances from centers of the face-to-face regions to the corresponding rotation axes are equal.

3. The capacitive micromechanical accelerometer according to claim 2, wherein in a direction perpendicular to an extending direction of the seesaw structures, the anchor points connected to the two seesaw structures directly face to each other; or,
in the direction perpendicular to the extending direction of the seesaw structures, the anchor points connected to the two seesaw structures are staggered; and the same ends of the two seesaw structures are flush with each other.

4. The capacitive micromechanical accelerometer according to claim 1, wherein the detection electrode comprises an out-plane electrode; and the out-plane electrode is spaced apart from board surfaces of the seesaw structures and forms a corresponding out-plane detection capacitor.

5. The capacitive micromechanical accelerometer according to claim 4, wherein the detection electrode comprises an out-plane electrode; and the out-plane electrode and the seesaw structures form out-plane detection capacitors respectively; or,
the detection electrode comprises two out-plane electrodes; the out-plane electrodes and the various seesaw structures respectively form out-plane detection capacitors; and the two out-plane electrodes and two sides of the corresponding rotation axis of the same seesaw structure form corresponding out-plane detection capacitors.

6. The capacitive micromechanical accelerometer according to claim 5, wherein the capacitive micromechanical accelerometer comprises two detection structure pairs; a lengthwise extending direction of the seesaw structures of one detection structure pair is in the first direction, and a lengthwise extending direction of the seesaw structures of the other detection structure pair is in the second direction; and the first direction and the second direction are perpendicular to each other.

7. The capacitive micromechanical accelerometer according to claim 6, wherein the two detection structure pairs are in rectangular arrangement; the two seesaw structures of one detection structure pair are respectively arranged on two opposite side edges of the rectangle;
and the two seesaw structures of the other detection structure pair are respectively arranged on the other two opposite side edges of the rectangle.

8. The capacitive micromechanical accelerometer according to claim 1, wherein the detection electrode comprises an in-plane electrode; and the in-plane electrode is spaced apart from side surfaces of the seesaw structures and forms a corresponding in-plane detection capacitor.

9. The capacitive micromechanical accelerometer according to claim 8, wherein the detection electrode comprises an in-plane electrode; and the in-plane electrode and the seesaw structures form in-plane detection capacitors respectively; or,
the detection electrode comprises two in-plane electrodes; the in-plane electrodes and the various seesaw structures respectively form in-plane detection capacitors; and the two in-plane electrodes are respectively located on two opposite sides of the same seesaw structure to form corresponding in-plane detection capacitors.

10. The capacitive micromechanical accelerometer according to claim 8, wherein the accelerometer further comprises an upper cover that is arranged, in a spacing manner, on one side of each detection structure pair facing away from the base; and the detection electrode is arranged on the base and/or the upper cover.
